(19) United States
(12) Patent Application Publication
(10) Pub. No.: US 2006/0084245 A1
(43) Pub. Date: Apr. 20, 2006

(54) Semiconductor device, semiconductor device production method, and substrate for the semiconductor device

(76) Inventor: Shinichi Kohda, Kyoto-shi (JP)

Correspondence Address: RABIN & Berdo, PC, 1101 14TH STREET, NW, SUITE 500, WASHINGTON, DC, 20005, US

(21) Appl. No.: 11/231,822

(22) Filed: Sep. 22, 2005

(30) Foreign Application Priority Data
Oct. 18, 2004 (JP) 2004-302975

(51) Int. Cl. H01L 21/20

(52) U.S. Cl. 438/478

(57) ABSTRACT

A semiconductor device production method includes the steps of: forming a linear gallium nitride stripe pattern on a major surface of a substrate, the major surface of the substrate being offset from a predetermined crystal plane by offset angles of 0.1 degree to 0.5 degrees respectively defined with respect to a first crystal axis and a second crystal axis parallel to the predetermined crystal plane, the linear gallium nitride stripe pattern extending along the first crystal axis; and growing a gallium nitride compound semiconductor crystal along the predetermined crystal plane by selective lateral epitaxial growth to form a gallium nitride compound semiconductor layer on the major surface of the substrate formed with the gallium nitride stripe pattern. The first crystal axis and the second crystal axis may be perpendicular to each other. The substrate may be a sapphire substrate, a silicon carbide substrate, an aluminum nitride substrate or a gallium nitride substrate. In this case, the predetermined crystal plane is preferably a C-plane.

### BACKGROUND OF THE INVENTION

1. Field of the Invention

The present invention relates to a semiconductor device based on a gallium nitride compound semiconductor, a production method for the semiconductor device, and a substrate for the semiconductor device.

2. Description of Related Art

Gallium nitride (GaN) compound semiconductors are represented by a general formula InₓAl_{y}Ga_{1-x-y}N (0≦x<1, 0≦y<1, 0≦x+y<1). Since the gallium nitride compound semiconductors have different band gaps within the range of 1.95 eV to 6 eV depending on their compositions, the gallium nitride compound semiconductors are attractive as materials for light emitting devices having a wide range of wavelengths from the ultraviolet to the infrared.

In a typical production process for a semiconductor light emitting device based on such a GaN compound semiconductor, a light emitting diode structure is produced by forming a GaN compound crystal layer on a sapphire monocrystalline substrate with the intervention of a buffer layer by epitaxial growth. However, a multiplicity of crystal defects called “dislocation” occur in the GaN compound crystal due to lattice mismatch between the sapphire substrate and GaN, thereby adversely influencing device characteristics. To cope with this, it has been proposed that selective lateral epitaxial growth is employed for improvement of the crystallinity of the GaN compound crystal.

More specifically, a thin GaN film is formed as an underlying film on the sapphire substrate with the intervention of the buffer layer, and then a stripe pattern mask is formed on the surface of the thin GaN film. By utilizing crystal nuclei provided by portions of the GaN film uncovered with the mask, the GaN compound crystal is grown selectively vertically (perpendicularly to the substrate) as projecting from the mask. Thereafter, the crystal growth conditions are changed to grow the GaN compound crystal selectively laterally (parallel to the substrate), whereby GaN compound crystal portions grown in mask openings are joined together.

However, the GaN compound crystal layer formed by the selective lateral growth is poor in surface planarity. This is supposedly because of the following mechanism. 006 It is herein assumed that a thin GaN film is formed as an underlying layer on a sapphire substrate having a major surface defined by a C-plane (just plane) and a GaN compound crystal is grown on the thin GaN film by the selective lateral growth. In this case, the surface of the underlying thin GaN film is defined by a C-plane (just plane), so that a smaller number of steps and kinks are present in the surface of the thin GaN film. Therefore, material atoms are less likely to reach the steps and kinks, resulting in so-called island growth of the GaN compound crystal as schematically illustrated in FIG. 13. This deteriorates the planarity.

A conceivable approach to this problem is to use a substrate having a major surface offset from the C-plane by a predetermined offset angle. That is, a surface of a GaN film formed on the surface of the substrate offset from the C-plane has steps as shown in FIG. 14. Therefore, it is supposed that material atoms can more easily reach the steps to permit step-flow growth of the GaN compound crystal, whereby the resulting GaN compound crystal layer has a surface excellent in planarity.

### SUMMARY OF THE INVENTION

The inventor of the present invention made an experiment by using a substrate having an offset angle defined parallel to the stripe pattern of the mask and a substrate having an offset angle defined perpendicularly to the stripe pattern of the mask for the selective lateral growth of the GaN compound crystal.

Where the substrate having the offset angle defined parallel to the stripe pattern was used, GaN compound crystal portions grown in the openings of the stripe pattern mask were excellent in planarity. However, it was impossible to eliminate height differences occurring at junctions of the GaN compound crystal portions grown from the mask openings, failing to achieve excellent planarity. This is supposedly because the crystal growth in a direction perpendicular to the stripe pattern occurs under the same conditions as the crystal growth on the C-plane (just plane).

Where the substrate having the offset angle defined perpendicularly to the stripe pattern is used, GaN compound crystal portions grown in the openings of the stripe pattern mask were poor in planarity. As a result, it was impossible to achieve excellent planarity. This is supposedly because the crystal growth in a direction parallel to the stripe pattern occurs under the same conditions as the crystal growth on the C-plane (just plane).

It is therefore an object of the present invention to provide a semiconductor device production method which ensures that a gallium nitride compound semiconductor layer having excellent planarity can be formed on a substrate.

It is another object of the present invention to provide a substrate suitable for the semiconductor device production method.

It is further another object of the present invention to provide a semiconductor device produced by using the substrate.

The method according to the present invention comprises the steps of: forming a linear gallium nitride stripe pattern on a major surface of a substrate, the major surface of the substrate being offset from a predetermined crystal plane by offset angles of 0.1 degree to 0.5 degrees respectively defined with respect to a first crystal axis and a second crystal axis parallel to the predetermined crystal plane, the linear gallium nitride stripe pattern extending along the first crystal axis; and growing a gallium nitride compound semiconductor crystal along the predetermined crystal plane by selective lateral epitaxial growth to form a gallium nitride compound semiconductor layer on the major surface of the substrate formed with the gallium nitride stripe pattern.

In this method, the major surface of the substrate is offset from the predetermined crystal plane by offset angles of not smaller than 0.1 degree and not greater than 0.5 degrees respectively defined with respect to the first and second crystal axes. Therefore, where the gallium nitride compound semiconductor layer is formed on the major surface by the selective lateral epitaxial growth utilizing crystal nuclei provided by the linear gallium nitride stripe pattern extending along the first crystal axis, the gallium nitride compound semiconductor crystal is properly grown with respect to the first crystal axis and the second crystal axis by step-flow growth. This suppresses the island growth, so that the gallium nitride compound semiconductor layer is formed as having excellent planarity.

By the selective lateral epitaxial growth on the gallium nitride stripe pattern, the gallium nitride compound crystal is grown in a stripe configuration conformal to the stripe pattern to form striped gallium nitride compound semiconductor portions, and further grown to join the striped gallium nitride compound semiconductor portions together. Where one of the offset angles is defined with respect to a direction parallel to the stripe pattern, the semiconductor layer has excellent planarity with respect to the direction parallel to the stripe pattern. Further, the other offset angle is defined with respect to a direction perpendicular to the stripe pattern, so that height differences between the striped gallium nitride compound semiconductor portions are eliminated by the step-flow growth after the striped portions are joined together. Thus, the gallium nitride compound semiconductor layer has excellent planarity with respect to the direction perpendicular to the stripe pattern.

If the offset angles are smaller than 0.1 degree, the number of steps in the major surface of the substrate is reduced. Therefore, material atoms are less likely to reach the steps in the major surface of the substrate, so that the island growth may occur. If the offset angles are greater than 0.5 degrees, there is a possibility that the height differences are not eliminated after the striped gallium nitride compound semiconductor portions are joined together.

The linear gallium nitride stripe pattern is formed along the first crystal axis. This means that the direction parallel to the stripe pattern is substantially aligned with the first crystal axis as seen perpendicularly to the major surface of the substrate, but does not mean in a strict sense that the direction parallel to the stripe pattern is parallel to the first crystal axis. In reality, the major surface of the substrate has the offset angle defined with respect to the first crystal axis, so that the first crystal axis is not parallel to the direction parallel to the stripe pattern as seen along the second crystal axis.

The selective lateral epitaxial growth is carried out under crystal growth conditions which ensure stable step-flow growth along the predetermined crystal plane, whereby the gallium nitride compound semiconductor layer is formed as having a surface with the same plane orientation as the predetermined crystal plane.

The major surface of the substrate herein means a surface of the substrate other than end faces of the substrate.

The substrate with its major surface off set from the crystal plane can be prepared, for example, by precisely polishing the surface of the substrate.

The first crystal axis and the second crystal axis are preferably perpendicular to each other. Thus, the direction perpendicular to the stripe pattern is aligned with the second crystal axis. Since an offset angle of 0.1 degree to 0.5 degrees is defined with respect to the direction perpendicular to the stripe pattern, the height differences can be more assuredly eliminated after the striped gallium nitride compound semiconductor portions are joined together.

The direction perpendicular to the stripe pattern is substantially aligned with the second crystal axis as seen perpendicularly to the major surface of the substrate, but offset from the second crystal axis by the corresponding offset angle as seen along the first crystal axis. That is, the substantial alignment of the direction perpendicular to the stripe pattern with the second crystal axis does not mean in a strict sense that the direction perpendicular to the stripe pattern is parallel to the second crystal axis.

The substrate may be a sapphire (Al₂O₃) substrate, a silicon carbide (SiC) substrate, an aluminum nitride (AlN) substrate or a gallium nitride (GaN) substrate. In this case, the predetermined crystal plane is preferably a C-plane.

In this case, the crystal axes parallel to the C-plane are A- and M-axes, which are perpendicular to each other. Where the first crystal axis is the A-axis, the second crystal axis is the M-axis. Where the first crystal axis is the M-axis, the second crystal axis is the A-axis. In either case, the substrate has a major surface offset from the C-plane by an offset angle of 0.1 degree to 0.5 degrees defined with respect to the A-axis and the M-axis. Thus, the epitaxial growth is carried out under crystal growth conditions which ensure stable step-flow growth along the C-plane, whereby the gallium nitride compound semiconductor layer can be formed as having a surface substantially parallel to the major surface of the substrate.

Where the substrate is an LiNbO₃ (lithium niobate) substrate, the predetermined crystal plane is preferably a (100) plane. In this case, the gallium nitride compound semiconductor layer can be formed on a major surface of the LiNbO₃ substrate offset from the (100) plane of the substrate by offset angles respectively defined with respect to the two crystal axes, so that the gallium nitride compound semiconductor layer has a surface excellent in planarity.

Where the substrate is a silicon substrate, the predetermined crystal plane is preferably a (111) plane. In this case, the gallium nitride compound semiconductor layer can be formed on a major surface of the silicon substrate offset from the (111) plane of the substrate by offset angles respectively defined with respect to the two crystal axes, so that the gallium nitride compound semiconductor layer has a surface excellent in planarity.

The stripe forming step preferably comprises the step of forming a linear stripe mask having linear openings along the first crystal axis for suppressing the growth of the gallium nitride compound semiconductor crystal to define striped linear gallium nitride exposure portions exposed from the openings of the mask.

In this method, the gallium nitride exposure portions exposed from the mask openings define the linear gallium nitride stripe pattern. The gallium nitride compound semiconductor layer can be formed as covering the major surface of the substrate by epitaxial growth from the gallium nitride exposure portions.

The gallium nitride exposure portions may be exposed surface portions of a gallium nitride compound semiconductor film formed on the major surface of the substrate. Where the gallium nitride substrate is used as the substrate, the gallium nitride exposure portions may be exposed surface portions of the substrate.

The stripe forming step preferably comprises the step of forming undulations in a linear stripe pattern along the first crystal axis in the major surface of the substrate.

A gallium nitride compound semiconductor film may be formed as an underlying film on the major surface of the substrate formed with the undulations in the linear stripe pattern, and the formation of the gallium nitride compound semiconductor layer may be achieved by epitaxial growth utilizing crystal nuclei provided by the underlying gallium nitride compound semiconductor film. Where the gallium nitride substrate is used as the substrate, the formation of the gallium nitride compound semiconductor layer may be achieved by epitaxial growth from the major surface of the substrate formed with the undulations. Alternatively, a mask may be formed on linear projections of the linear stripe pattern, and the formation of the gallium nitride compound semiconductor layer may be achieved by epitaxial growth from gallium nitride exposure portions exposed in linear recesses of the linear stripe pattern.

The method preferably further comprises the step of forming a gallium nitride compound semiconductor film as an underlying film on the major surface of the substrate. In this method, the formation of the underlying gallium nitride compound semiconductor film expands the range of choices of substrate materials. This facilitates the production of a semiconductor device.

The stripe forming step may comprise the step of processing the underlying gallium nitride compound semiconductor film into a linear stripe pattern extending along the first crystal axis. In this method, the underlying gallium nitride compound semiconductor film is processed into the linear stripe pattern, so that the gallium nitride compound semiconductor layer is formed as having excellent surface planarity by epitaxial growth from the under lying gallium nitride compound semiconductor film.

The underlying gallium nitride compound semiconductor film maybe patterned into the linear stripe pattern, or processed to be formed with undulations in the linear stripe pattern.

Where the underlying gallium nitride compound semiconductor film is processed to be formed with the undulations in the linear stripe pattern, a mask may be formed on linear projections of the linear stripe pattern of the underlying gallium nitride compound semiconductor film, and the formation of the gallium nitride compound semiconductor layer may be achieved by epitaxial growth from gallium nitride exposure portions exposed in linear recesses of the linear stripe pattern.

For example, the gallium nitride compound semiconductor film may be first formed on the entire major surface of the substrate, and then processed to be formed with the undulations in the linear stripe pattern by forming a linear stripe pattern mask on the gallium nitride compound semiconductor film and etching the gallium nitride compound semiconductor film with the use of the linear stripe mask as an etching mask. Thereafter, the formation of the gallium nitride compound semiconductor layer is achieved by the epitaxial growth with the mask removed or with the mask left unremoved. Where the mask is left unremoved, the mask is preferably composed of a material which is capable of suppressing epitaxial growth of the gallium nitride compound semiconductor crystal from portions of the underlying gallium nitride compound semiconductor film covered with the mask and is resistant to an etching medium to be used for the etching of the underlying gallium nitride compound semiconductor film.

Where the underlying gallium nitride compound semiconductor film is patterned into the stripe pattern, portions of the underlying gallium nitride compound semiconductor film uncovered with the mask are completely etched away, and then the mask is removed.

The epitaxial growth step for the formation of the gallium nitride compound semiconductor layer may comprise the step of adding an impurity of a first conductivity during the epitaxial growth so that the gallium nitride compound semiconductor layer is formed as having the first conductivity. In this case, the method preferably further comprises the steps of: forming an active layer on the gallium nitride compound semiconductor layer, the active layer being capable of emitting light by recombination of an electron and a positive hole; and forming a second gallium nitride compound semiconductor layer having a second conductivity different from the first conductivity on the active layer.

This method makes it possible to produce a light emitting diode structure. In the light emitting diode structure, carriers are injected into the active layer from the gallium nitride compound semiconductor layer of the first conductivity and the gallium nitride compound semiconductor layer of the second conductivity, whereby positive holes and electrons are recombined in the active layer to provide light emission. Thus, a gallium nitride compound semiconductor light emitting device can be produced.

Since the gallium nitride compound semiconductor layer of the first conductivity is excellent in surface planarity, the active layer and the gallium nitride compound semiconductor layer of the second conductivity formed on the gallium nitride compound semiconductor layer of the first conductivity are excellent in crystallinity. Thus, the light emitting device has an excellent light emitting efficiency.

The substrate according to the present invention has a major surface offset from a predetermined crystal plane by offset angles of 0.1 degree to 0.5 degrees respectively defined with respect to a first crystal axis and a second crystal axis parallel to the predetermined crystal plane. With the use of the substrate, a gallium nitride compound semiconductor layer can be formed on the major surface of the substrate a shaving a surface excellent in planarity.

The semiconductor device according to the present invention comprises a substrate having a major surface offset from a predetermined crystal plane by offset angles of 0.1 degree to 0.5 degrees respectively defined with respect to a first crystal axis and a second crystal axis parallel to the predetermined crystal plane, and a gallium nitride compound semiconductor layer formed on the major surface of the substrate by epitaxial growth. With this arrangement, the gallium nitride compound semiconductor layer formed on the major surface of the substrate has a surface excellent in planarity, so that the characteristic properties of the semiconductor device can be improved.

The gallium nitride compound semiconductor layer maybe a gallium nitride compound semiconductor layer having a first conductivity. The semiconductor device preferably further comprises: an active layer provided on the gallium nitride compound semiconductor layer, the active layer being capable of emitting light by recombination of an electron and a positive hole; and a gallium nitride compound semiconductor layer provided on the active layer and having a second conductivity different from the first conductivity.

With this arrangement, carriers are injected into the active layer from the gallium nitride compound semiconductor layer of the first conductivity and the gallium nitride compound semiconductor layer of the second conductivity, whereby positive holes and electrons are recombined in the active layer to provide light emission. Since the gallium nitride compound semiconductor layer of the first conductivity has a surface excellent in planarity, the active layer and the gallium nitride compound semiconductor layer of the second conductivity provided on the gallium nitride compound semiconductor layer of the first conductivity are excellent in crystallinity. Thus, a light emitting device excellent in light emitting efficiency can be provided.

The semiconductor device preferably further comprises: a first electrode connected to the gallium nitride compound semiconductor layer of the first conductivity (through ohmic contact); and a second electrode connected to the gallium nitride compound semiconductor layer of the second conductivity (through ohmic contact).

The foregoing and other objects, features and effects of the present invention will become more apparent from the following description of the preferred embodiments with reference to the attached drawings.

### BRIEF DESCRIPTION OF THE DRAWINGS

FIGS. 1(a) to 1(e) are sectional views illustrating steps of a semiconductor device production method according to a first embodiment of the present invention;

FIGS. 2(a) to 2(c) are schematic diagrams illustrating the structure of a substrate;

FIG. 3 is a schematic sectional view illustrating how epitaxial growth proceeds for formation of a GaN compound semiconductor layer without selective vertical epitaxial growth in the first embodiment;

FIGS. 4(a) to 4(e) are sectional views illustrating steps of a semiconductor device production method according to a second embodiment of the present invention;

FIGS. 5(a) and 5(b) are schematic sectional views illustrating how epitaxial growth proceeds for formation of a GaN compound semiconductor layer with a mask left unremoved in the second embodiment;

FIGS. 6(a) and 6(b) are schematic sectional views illustrating how epitaxial growth proceeds for formation of a GaN compound semiconductor layer with an underlying GaN film patterned in a linear stripe pattern in the second embodiment;

FIG. 7 is a schematic sectional view illustrating how epitaxial growth proceeds for formation of a GaN compound semiconductor layer without selective vertical epitaxial growth in the second embodiment;

FIGS. 8(a) to 8(e) are sectional views illustrating steps of a semiconductor device production method according to a third embodiment of the present invention;

FIG. 9 is a schematic sectional view illustrating how epitaxial growth proceeds for formation of a GaN compound semiconductor layer without selective vertical epitaxial growth in the third embodiment;

FIGS. 10(a), 10(b) and 10(c) are sectional views illustrating steps of a method for producing a gallium nitride semiconductor light emitting device;

FIG. 11 is a schematic sectional view illustrating an exemplary construction of a gallium nitride semiconductor light emitting device of a mesa type;

FIG. 12 is a schematic sectional view illustrating an exemplary construction of a gallium nitride semiconductor light emitting device having high resistance layers for current narrowing;

FIG. 13 is a schematic diagram for explaining island growth of a GaN compound crystal on a C-plane (just plane) and

FIG. 14 is a schematic diagram for explaining step-flow growth of the GaN compound crystal.

### DETAILED DESCRIPTION OF PREFERRED EMBODIMENTS

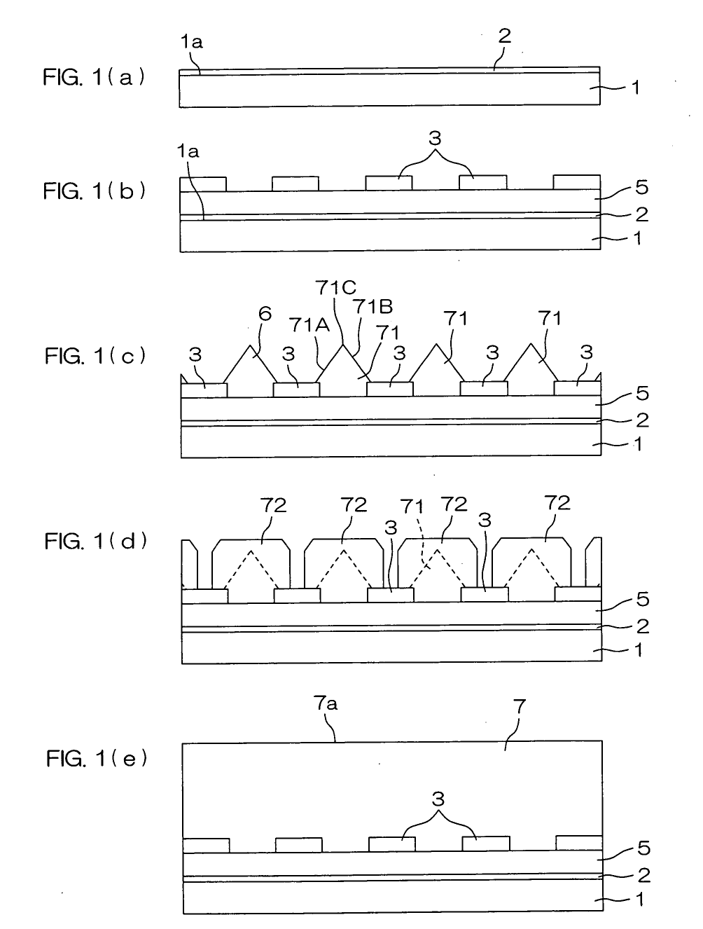

FIGS. 1(a) to 1(e) are sectional views illustrating steps of a semiconductor device production method according to a first embodiment of the present invention. A substrate 1 composed of sapphire, crystalline silicon carbide or crystalline aluminum nitride is prepared. The substrate 1 has a major surface la offset from a C-plane by a predetermined offset angle. A buffer layer 2 is formed on the major surface 1a of the substrate 1 (see FIG. 1(a)). The buffer layer 2 is composed of a Group III nitride compound represented by Inₓ₁Al_{y1}Ga_{1-x1-y1}N (0≦x1≦1, 0≦y1≦1, 0≦x1+y1≦1). The formation of the buffer layer 2 may be achieved, for example, by an epitaxial growth method such as an MOCVD (metal-organics chemical vapor deposition) method. The buffer layer 2 has a thickness of about 200 Å, for example.

A GaN compound semiconductor film 5 (hereinafter referred to as “underlying GaN film 5”) is formed as an underlying film on the buffer layer 2 to provide crystal nuclei for crystal growth (see FIG. 1(b)). The underlying GaN film 5 is composed of a GaN compound semiconductor represented by a general formula Inₓ₂Al_{y2}Ga_{1-x2-y2}N (0≦x2<1, 0≦y2<1, 0≦x2+y2<1). The formation of the underlying GaN film 5 may be achieved by an epitaxial growth method such as an MOCVD method. The underlying GaN film 5 has a multiplicity of crystal defects (dislocation defects) which are carried over from the buffer layer 2. The underlying GaN film 5 has a thickness of about lam, for example.

A plurality of mask layers 3 are formed, for example, in an equidistant stripe pattern on the underlying GaN film 5 (see FIG. 1(b)). In this embodiment, the equidistant stripe pattern of the mask layers 3 is a linear stripe pattern having a plurality of linear parallel stripes. The linear stripe pattern extends along an A-axis as seen in plan perpendicularly to the major surface 1a of the substrate 1. The mask layers 3 are composed of a material on which the GaN compound crystal is less liable to grow. Examples of the material for the mask layers 3 include SiO₂, SiNₓ, W, TiN and ZrO₂. More specifically, where SiO₂ or SiNₓ is used as the material for the mask layers 3, a layer of the material is formed on the entire surface of the underlying GaN film 5 by a sputtering method, a CVD (chemical vapor deposition) method or a vapor deposition method, and a resist is applied on the entire surface of the material layer. After the resulting resist film is patterned by photolithography, the material layer is wet-etched with the use of the patterned resist film as a mask. Thus, the SiO₂ or SiNₓ film is shaped into the stripe pattern to provide the mask layers 3.

In turn, a GaN compound semiconductor represented by a general formula Inₓ₃Al_{y3}Ga_{1-x3-y3}N (0≦x3<1, 0≦y3<1, 0≦x3+y3<1) is deposited on surface portions of the underlying GaN film 5 uncovered with the mask layers 3 by selective vertical epitaxial growth (FIG. 1(c)). More specifically, the crystal of the GaN compound semiconductor is grown under conditions (at a crystal growth temperature and a chamber internal pressure) which ensure easy vertical growth of the GaN compound semiconductor crystal by utilizing crystal nuclei provided by the uncovered portions of the underlying GaN film 5. Thus, the GaN compound semiconductor crystal is grown from the striped surface portions of the underlying GaN film 5 uncovered with the stripe pattern mask layers 3 to form selective vertical growth portions 71 of a ridge shape along the stripe pattern. The selective vertical growth portions 71 each have a pair of surfaces 71A, 71B inclined with respect to the major surface 1a of the substrate 1 and a ridge line 71C extending along the stripe pattern of the mask layers 3. At this time, the inclined surfaces 71A, 71B are each defined by an R-plane of the GaN compound semiconductor crystal. That is, the GaN compound semiconductor crystal is grown under conditions which stabilize the R-plane. Thus, the formation of the selective vertical growth portions 71 can be achieved by the selective vertical epitaxial growth.

In turn, the GaN compound semiconductor crystal is further grown selectively laterally from the selective vertical growth portions 71 along the major surface 1a of the substrate 1 (FIG. 1(d)). More specifically, the GaN compound semiconductor crystal is grown from the selective vertical growth portions 71 under conditions (at a crystal growth temperature and a chamber internal pressure) which ensure easy lateral growth of the crystal. Thus, the GaN compound semiconductor crystal is laterally grown on the mask layers 3 from the ridge-shaped selective vertical growth portions 71 to form a plurality of GaN compound semiconductor layers 72 (selective lateral growth portions) each having a flat top face in a stripe configuration (see FIG. 1(d)), and further laterally grown to join the GaN compound semiconductor layers 72 together. Thus, a unitary GaN compound semiconductor layer 7 is provided (see FIG. 1(e)).

The GaN compound semiconductor layer 7 has a flat surface 7a substantially parallel to the major surface la. The surface 7a of the GaN compound semiconductor layer 7 is defined by a C-plane of the GaN compound semiconductor crystal. In other words, the GaN compound semiconductor crystal is grown under conditions which stabilize the C-plane for the selective lateral epitaxial growth. The GaN compound semiconductor layer 7 has a thickness (or a height) of about 1.5 μm, for example, as measured from the surface of the buffer layer 2.

The multiplicity of dislocation defects present in the underlying GaN film 5 are carried over into the selective vertical growth portions 71 formed by the selective vertical growth. Thus, the selective vertical growth portions 71 have vertical dislocation lines. The dislocation defects present in the selective vertical growth portions 71 are carried over laterally into the GaN compound semiconductor layer 7 formed by the selective lateral growth, but dislocation defects present in portions of the underlying GaN film 5 covered with the mask layers 3 are not carried over into the GaN compound semiconductor layer 7. Thus, the number of dislocation defects appearing on the surface of the GaN compound semiconductor layer 7 can be reduced.

The epitaxial growth for the formation of the buffer layer 2, the underlying GaN film 5 and the GaN compound semiconductor layer 7 may be achieved by a liquid phase epitaxial growth method, a vapor phase epitaxial growth method or a molecular beam epitaxial growth method. The liquid phase epitaxial growth is such that a crystal is deposited from a supersaturated solution while equilibrium between the solid phase and the liquid phase is maintained. The vapor phase epitaxial growth is such that a crystal is grown at a pressure ranging from several Torrs to an atmospheric pressure by passing a material gas. The molecular beam epitaxial growth (MBE) is such that molecules or atoms of constituent elements of a crystal to be grown are supplied in the form of a molecular beam onto a substrate in an ultrahigh vacuum. Particularly excellent epitaxial growth methods include a halide vapor phase growth (HVPE) method, a molecular beam epitaxial (MBE) method and a metal-organics chemical vapor deposition (MOCVD) method, which are applicable to the crystal growth for the formation of the buffer layer 2, the underlying GaN film 5 and the GaN compound semiconductor layer 7.

To impart the GaN compound semiconductor layer 7 with an N-conductivity, an N-type dopant such as Si may be added during the epitaxial growth. To impart the GaN compound semiconductor layer 7 with a P-conductivity, a P-type dopant such as Mg may be added during the epitaxial growth.

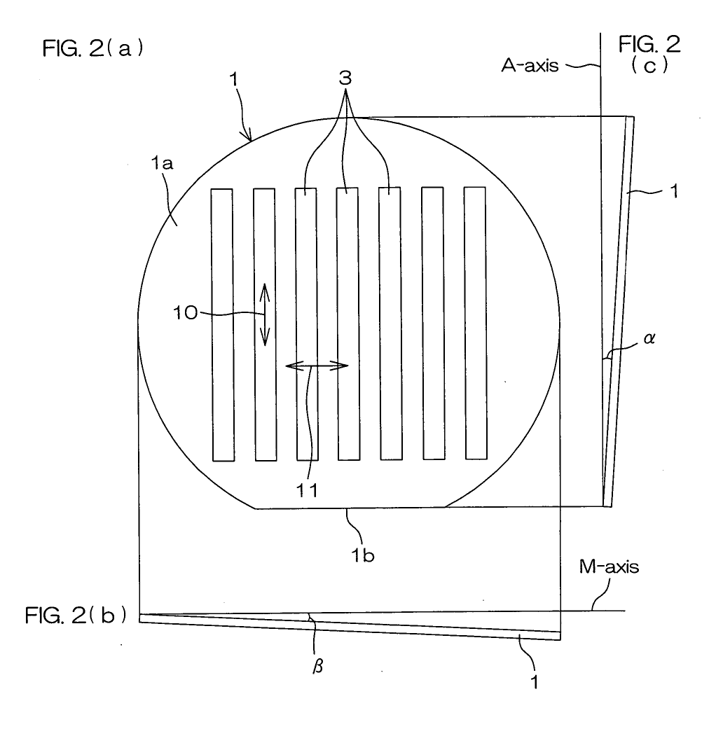

FIG. 2(a) is a schematic plan view of the substrate 1. FIG. 2(b) is a schematic front view of the substrate 1 as seen from the side of an orientation flat surface 1b of the substrate 1, and FIG. 2(c) is a schematic side view of the substrate 1 as seen perpendicularly to the orientation flat surface 1b.

In this embodiment, the substrate 1 is generally round, and has an orientation flat surface 1b which defines a crystal plane orientation. In this embodiment, the orientation flat surface 1b is defined by an A-plane. The major surface 1a of the substrate 1 is tilted (offset) by an angle (offset angle) α with respect to an A-axis which is normal to the A-plane, and tilted (offset) by an angle (offset angle) β with respect to an M-axis which is perpendicular to the A-axis (which is normal to an M-plane perpendicular to the A-plane and a C-plane). In other words, the major surface 1a is offset from the C-plane (including the A-axis and the M-axis) with respect to the two directions which are perpendicular to each other.

The offset angles α, β are each defined in the range of 0.1 degree to 0.5 degrees (0.1 degree<(x≦α≦0.5 degrees, 0.1 degree≦β≦0.5 degrees), and may be α=β or α≠β (α>β or α<β).

The stripe pattern of the mask layers 3 formed on the major surface 1a is linear and parallel to the A-axis. Therefore, the major surface 1a of the substrate 1 is a two-directionally offset surface which is offset from the C-plane by the offset angle α defined with respect to a direction 10 parallel to the stripes (hereinafter referred to simply as “parallel direction 10”), and offset from the C-plane by the offset angle β defined with respect to a direction 11 perpendicular to the stripes (hereinafter referred to simply as “perpendicular direction 11”).

The offset angles of the major surface 1a of the substrate 1 are carried over to the underlying GaN film 5. That is, the surface of the underlying GaN film 5 is a two-directionally offset surface which is offset from the C-plane by the offset angle α defined with respect to the parallel direction 10, and offset from the C-plane by the offset angle β defined with respect to the perpendicular direction 11. Therefore, the surface of the underlying GaN film 5 has a multiplicity of steps and kinks, so that supplied material atoms can easily reach the steps and the kinks. This makes it possible to promote the step-flow growth during the selective lateral epitaxial growth while suppressing the island growth. Thus, the GaN compound semiconductor layer 7 has excellent planarity.

More specifically, the surfaces of the striped GaN compound semiconductor layers 72 (see FIG. 1(d) ) each have a multiplicity of steps with respect to the parallel direction 10, so that the step-flow growth can be promoted during the selective lateral epitaxial growth. Thus, the GaN compound semiconductor layers 72 each have excellent planarity with respect to the parallel direction 10. Further, the surfaces of the striped GaN compound semiconductor layers 72 also have a multiplicity of steps with respect to the perpendicular direction 11, so that height differences between the striped GaN compound semiconductor layers 72 can be easily eliminated by the step-flow growth after the GaN compound semiconductor layers 72 are joined together. Thus, the GaN compound semiconductor layer 7 has excellent planarity.

In one example, a GaN compound semiconductor layer 7 was formed on a substrate 1 having an offset angle α of 0.22 degrees defined with respect to the A-axis and an offset angle β of 0.13 degrees defined with respect to the M-axis, and the surface roughness of the GaN compound semiconductor layer 7 was measured. As a result, the GaN compound semiconductor layer 7 had a surface roughness of 78 Å as measured in the parallel direction 10 and a surface roughness of 185 Å as measured in the perpendicular direction 11.

In a comparative example, a GaN compound semiconductor layer was formed on a substrate having an offset angle α of 0 degree defined with respect to the A-axis and an offset angle β of 0.25 degrees defined with respect to the M-axis, and the surface roughness of the GaN compound semiconductor layer was measured. As a result, the GaN compound semiconductor layer had a surface roughness of 241 Å as measured in the parallel direction 10 and a surface roughness of 384 Å as measured in the perpendicular direction 11.

Thus, drastic improvement in surface roughness was confirmed.

A relationship between the surface roughness of the GaN compound semiconductor layer 7 and the offset angles α, β is shown in Table 1.

TABLE 1

M-axis

| A-axis | 0° | 0.1° | 0.2° | 0.3° |
|---|---|---|---|---|
| 0° | 100 Å | 50 Å | 20 Å | 50 Å |
| 0.1° | 50 Å | 15 Å | 30 Å | 80 Å |
| 0.2° | 20 Å | 30 Å | 50 Å | 80 Å |
| 0.3° | 50 Å | 80 Å | 100 Å | 150 Å |

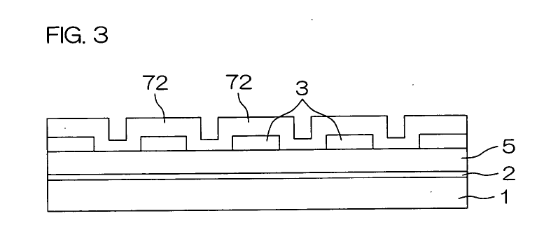

The selective vertical epitaxial growth from the underlying GaN film 5 is not necessarily required, but selective lateral epitaxial growth from the portions of the underlying GaN film 5 uncovered with the mask layers 3 may be carried out from the start for the formation of the GaN compound semiconductor layer 7. In this case, the GaN compound semiconductor layer 7 has a sectional structure as schematically illustrated in FIG. 3 in the midst of the formation of the layer 7. That is, the GaN compound semiconductor crystal is not grown into the ridge-shaped selective vertical growth layers 71, but grown in a stripe configuration from the start to form the GaN compound semiconductor layers 72 (selective lateral growth layers) each having a flat top face. Where the step shown in FIG. 3 is employed, however, the number of lower dislocation density regions in the surface 7a of the GaN compound semiconductor layer 7 is reduced as compared with the case where the steps shown in FIGS. 1(a) to 1(e) are employed. This is because the dislocation defects present in the underlying GaN film 5 are carried over vertically.

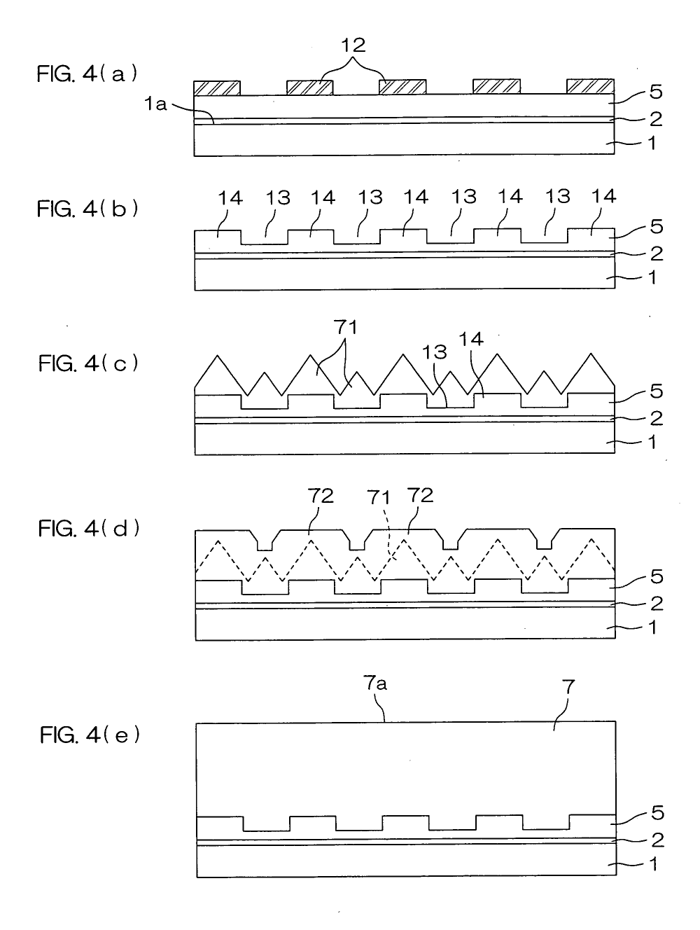

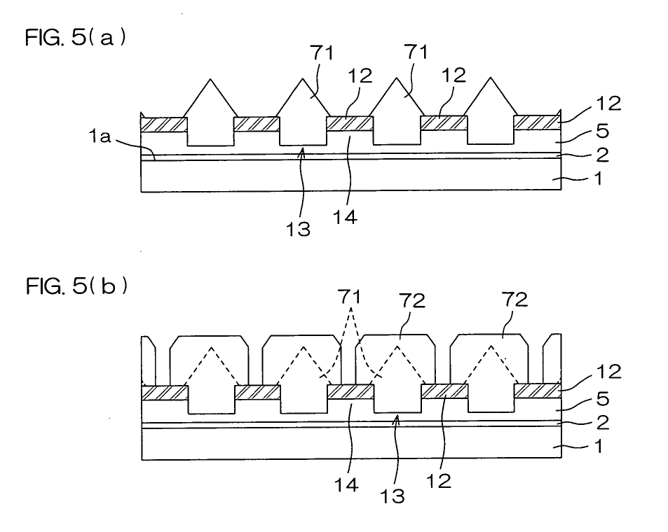

FIGS. 4(a) to 4(e) are sectional views illustrating steps of a semiconductor device production method according to a second embodiment of the present invention. In FIGS. 4(a) to 4(e), parts corresponding to those shown in FIGS. 1(a) to 1(e) will be denoted by the same reference characters as in FIGS. 1(a) to 1(e).

In this embodiment, a buffer layer 2 and an underlying GaN film 5 are formed on a substrate 1, and then undulations are formed in a stripe configuration in a surface of the underlying GaN film 5. More specifically, the formation of the undulations is achieved, for example, by forming a plurality of etching masks 12 in an equidistant stripe pattern (in a linear parallel stripe pattern in this embodiment) on the surface of the underlying GaN film 5 by photolithography (FIG. 4(a)) and forming a plurality of linear recesses (grooves) 13 in an equidistant stripe pattern in the surface of the underlying GaN film 5 by etching with the use of the etching masks 12 (FIG. 4(b) ). Portions of the underlying GaN film 5 immediately below the etching masks 12 serve as linear projections 14. Thus, the undulations are formed in the stripe configuration in the surface of the underlying GaN film 5.

The linear recesses 13 and the linear projections 14 extend along the A-axis as seen in plan perpendicularly to a major surface 1a of the substrate 1. Therefore, the surface of the underlying GaN film 5 which inherits the offset angles of the major surface of the substrate 1 is a two-directionally offset surface which is offset from the C-plane by the offset angle α defined with respect to the parallel direction 10 (see FIG. 2) and offset from the C-plane by the offset angle β defined with respect to the perpendicular direction 11 (see FIG. 2). The linear recesses 13 each have a depth of about 3 μm, for example.

After the etching masks 12 are removed, the GaN compound semiconductor crystal is grown by the selective vertical epitaxial growth to form selective vertical growth portions 71 each having a ridge shape (FIG. 4(c) The selective vertical growth portions 71 of the ridge shape on the linear projections 14 each have a greater height, while the selective vertical growth portions 71 of the ridge shape on the linear recesses 13 each have a smaller height.

Then, the GaN compound semiconductor crystal is grown by the selective lateral epitaxial growth to form a plurality of GaN compound semiconductor layers 72 (selective lateral growth portions) each having a flat top face in a stripe configuration (FIG. 4(d)), and further grown to join the GaN compound semiconductor layers 72 together. Thus, a GaN compound semiconductor layer 7 having a flat surface is formed over the surface of the substrate 1 (FIG. 4(e) ). In this embodiment, the surface of the underlying GaN film 5 which provides crystal nuclei is offset from the C-plane with respect to the two directions perpendicular to each other, like the major surface 1a of the substrate 1, so that the GaN compound semiconductor layer 7 can be formed through the step-flow growth by the selective lateral epitaxial growth. Thus, the island growth can be suppressed, so that the surface 7a of the GaN compound semiconductor layer 7 has excellent planarity.

During the selective lateral epitaxial growth from the selective vertical growth portions 71, the selective lateral growth portions formed over the selective vertical growth portions 71 of the higher ridge shape cover the selective lateral growth portions formed on the selective vertical growth portions 71 of the lower ridge shape. Thus, the dislocation density in the surface 7a of the GaN compound semiconductor layer 7 is minimized.

The etching masks 12 may be formed of a resist film. Alternatively, the etching masks 12 maybe composed of a material (e.g., SiO₂, SiNₓ, W, TiN or ZrO₂) on which the GaN compound semiconductor crystal is less liable to grow. In this case, as shown in FIGS. 5(a) and 5(b), the GaN compound semiconductor crystal may be grown by the selective vertical epitaxial growth (FIG. 5(a)) and then by the selective lateral epitaxial growth with the etching masks 12 left unremoved. In this case, the GaN compound semiconductor crystal is grown on the linear recesses 13 to form the GaN compound semiconductor layer 7.

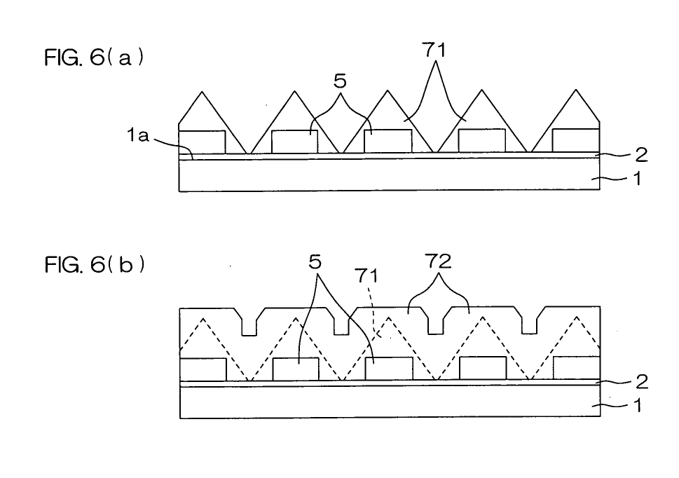

The formation of the linear recesses 13 may be achieved by dicing rather than by the etching.

Where the etching masks 12 are removed, the linear recesses 13 may be formed so as to reach the buffer layer 2 or reach the substrate 1. That is, the underlying GaN film 5 may be patterned in a linear stripe configuration. In this case, as shown in FIGS. 6(a) and 6(b), the GaN compound semiconductor crystal may be grown from the linear projections 14 by the selective vertical epitaxial growth (FIG. 6(a)) and then by the selective lateral epitaxial growth to form the striped GaN compound semiconductor layers 72, and further grown to join the striped GaN compound semiconductor layers 72 together. Thus, the GaN compound semiconductor layer 7 is formed over the surface of the substrate 1.

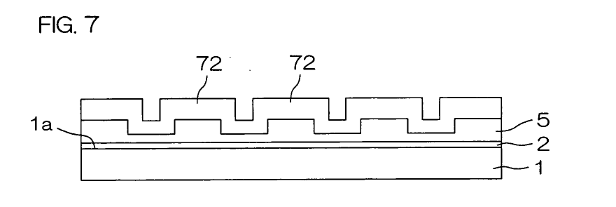

As in the first embodiment, the selective vertical growth from the underlying GaN film 5 is not necessarily required, but the GaN compound semiconductor crystal may be grown on the underlying GaN film 5 from the start by the selective lateral growth for the formation of the GaN compound semiconductor layer 7. In this case, the GaN compound semiconductor layer 7 has a sectional structure as schematically illustrated in FIG. 7 in the midst of the formation of the layer 7. That is, the GaN compound semiconductor crystal is not grown in a ridge shape, but grown in a stripe configuration from the start to form the GaN compound semiconductor layers 72 each having a flat top face.

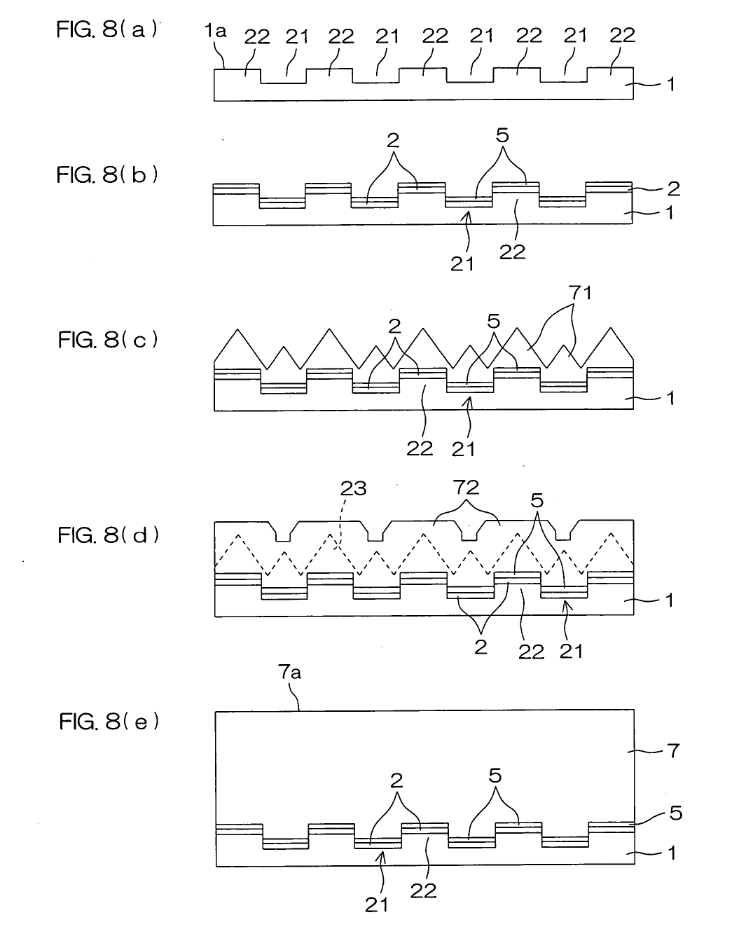

FIGS. 8(a) to 8(e) are sectional views illustrating steps of a semiconductor device production method according to a third embodiment of the present invention. In FIGS. 8(a) to 8(e), parts corresponding to those shown in FIGS. 1(a) to l(e) will be denoted by the same reference characters as in FIGS. 1(a) to 1(e).

In this embodiment, undulations are formed in a linear stripe pattern in a surface of a substrate 1 by etching or dicing (FIG. 8(a)). That is, a plurality of linear recesses 21 (grooves) are formed in an equidistant stripe pattern in the surface of the substrate 1, so that linear projections 22 are each defined between two adjacent linear recesses 21. Thus, the stripe pattern (linear parallel stripe pattern in this embodiment) is formed as having the plurality of linear recesses 21 and the plurality of linear projections 22. The linear recesses 21 each have a depth of about 3 μm, for example.

In this state, a buffer layer 2 (e.g., having a thickness of about 200 Å) is formed on the entire surface of the substrate 1, and an underlying GaN film 5 (e.g., having a thickness of about 1 μm) is formed on the buffer layer 2 (FIG. 8(b)). In FIG. 8(b), the underlying GaN film 5 is illustrated as a discontinuous film which includes film portions separately formed in the linear recesses 21 and on the linear projections 22 by way of example, but may be formed as a continuous film over the linear recesses 21 and the linear projections 22.

Thereafter, as shown in FIG. 8(c), the GaN compound semiconductor crystal is grown by the selective vertical epitaxial growth to form a plurality of selective vertical growth portions 71 each having a ridge shape in a stripe configuration. Then, as shown in FIG. 8(d), the GaN compound semiconductor crystal is grown by the selective lateral epitaxial growth to form GaN compound semiconductor layers 72 each having a flat top face in a stripe configuration, and further grown by the selective lateral epitaxial growth to form a flat GaN compound semiconductor layer 7 over the surface of the substrate as shown in FIG. 8(e).

The linear recesses 21 and-the linear projections 22 are formed along the A-axis as seen in plan perpendicularly to the major surface 1a of the substrate 1. Therefore, the underlying GaN film 5 inherits the offset angles of the substrate 1, so that the surface of the underlying GaN film 5 is a two-directionally offset surface which is offset from the C-plane by the offset angle α defined with respect to the parallel direction 10 and offset from the C-plane by the offset angle β defined with respect to the perpendicular direction 11.

Therefore, the GaN compound semiconductor layer 7 formed by the crystal growth utilizing crystal nuclei provided by the underlying GaN film 5 has a surface 7a excellent in planarity, because the GaN compound semiconductor crystal is grown by the step-flow growth during the selective lateral epitaxial growth.

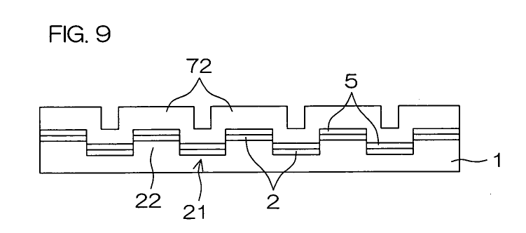

As in the first and second embodiments, the selective vertical growth from the underlying GaN film 5 is not necessarily required, but the GaN compound semiconductor crystal may be grown on the underlying GaN film 5 from the start by the selective lateral epitaxial growth for the formation of the GaN compound semiconductor layer 7. In this case, the GaN compound semiconductor layer 7 has a sectional structure as schematically illustrated in FIG. 9 in the midst of the formation of the layer 7. That is, the GaN compound semiconductor crystal is not grown in a ridge shape, but grown in a stripe configuration from the start to form the GaN compound semiconductor layers 72 each having a flat top face.

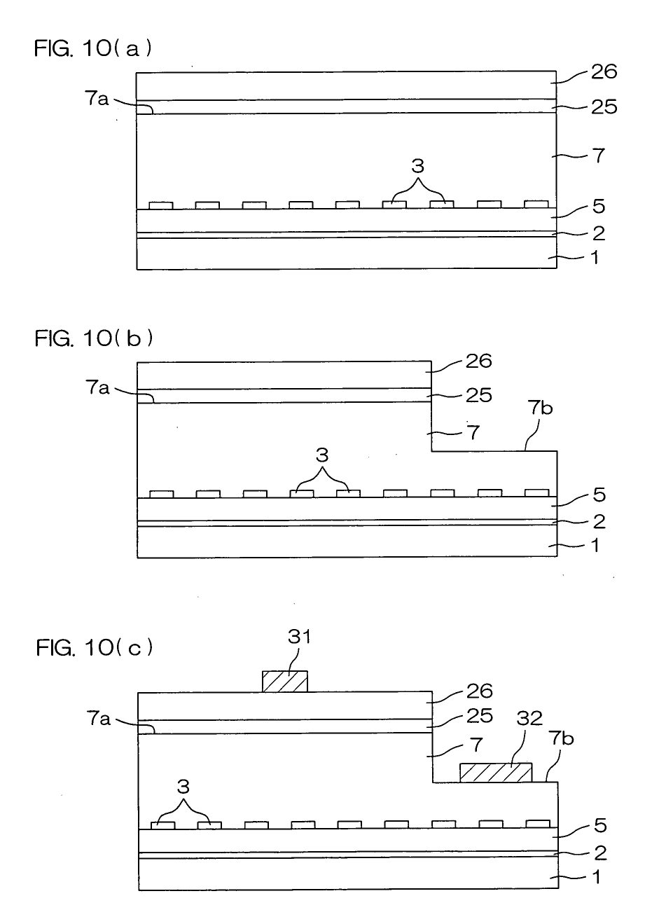

FIGS. 10(a), 10(b) and 10(c) are sectional views illustrating steps of a method for producing a gallium nitride semiconductor light emitting device by utilizing the steps shown in FIGS. 1(a) to 1(e). First, the steps shown in FIGS. 1(a) to 1(e) are performed to form a GaN compound semiconductor layer 7 on a substrate 1. The GaN compound semiconductor layer 7 is doped with an N-type dopant (e.g., Si), for example, during the epitaxial growth so as to provide an N-type GaN layer.

An active layer 25 is formed on the GaN compound semiconductor layer 7, for example, by epitaxial growth. Further, a layer 26 of a P-type GaN compound semiconductor represented by a general formula Inₓ₄Al_{y4}Ga_{1-x4-y4}N (0≦x4<1, 0≦y4<1, 0≦x4+y4<1) is formed on the active layer 25 by epitaxial growth (FIG. 10(a)). The active layer 25 is composed of, for example, a GaInN compound (a Group III nitride compound represented by a general formula Inₓ₅Al_{y5}Ga_{1-x5-y5}N (0≦x5≦1, 0≦y5≦1, 0≦x5+y5≦1). The N-type GaN compound semiconductor layer 7 and the P-type GaN compound semiconductor layer 26 may each have a single layer structure or a laminate structure including a plurality of layers having different compositions.

In turn, as shown in FIG. 10(b), the P-type GaN compound semiconductor layer 26, the active layer 25 and the N-type GaN compound semiconductor layer 7 are partly cut away so as to expose the N-type GaN compound semiconductor layer 7.

Then, as shown in FIG. 10(c), a P-side electrode 31 is formed so as to be connected to the P-type GaN compound semiconductor layer 26, and an N-side electrode 32 is formed so as to be connected to an exposed surface 7b of the N-type GaN compound semiconductor layer 7. When these electrodes 31, 32 are energized, electrons and positive holes are injected into the active layer 25 from the GaN compound semiconductor layers 7 and 26, respectively, whereby the electrons and the positive holes are recombined in the active layer 25 to provide light emission.

The P-side electrode 31 is connected to the P-type GaN compound semiconductor layer 26 through ohmic contact, and composed of, for example, Ni/Au (a laminate film including an Au lower layer in contact with the semiconductor layer 26), ZnO or ITO. The N-side electrode 32 is connected to the N-type GaN compound semiconductor layer 7 through ohmic contact, and composed of, for example, Ti/Al (a laminate film including an Al lower layer in contact with the semiconductor layer 7).

The methods shown in FIGS. 1(a) to 1(e) and FIGS. 3 to 9 may be employed for the formation of the GaN compound semiconductor layer 7. In any case, the steps shown in FIGS. 10(a) to 10(c) are thereafter performed, whereby the gallium nitride semiconductor light emitting device is provided.

Since the surface 7a of the N-type GaN compound semiconductor layer 7 is excellent in planarity, excellent interfaces are provided between the N-type GaN compound semiconductor layer 7 and the active layer 25 provided on the layer 7 and between the active layer 25 and the P-type GaN compound semiconductor layer 26. As a result, the light emitting device has an excellent light emitting efficiency.

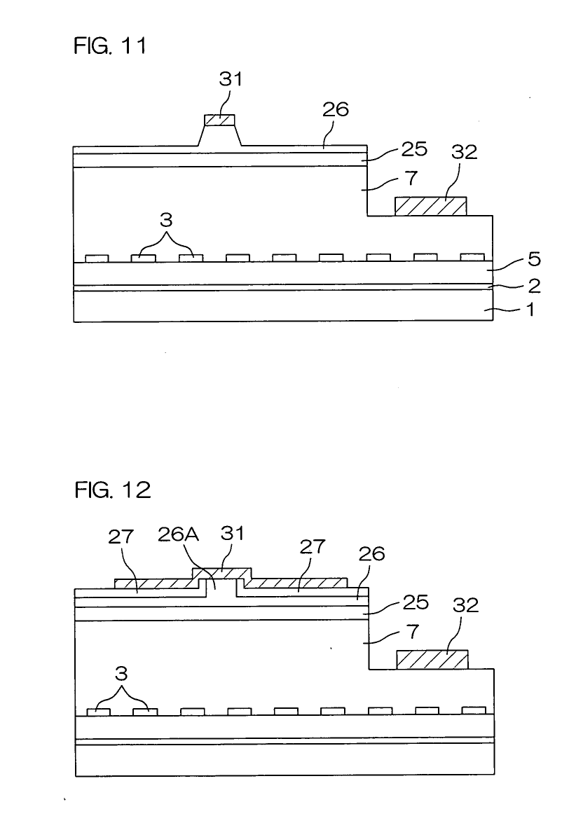

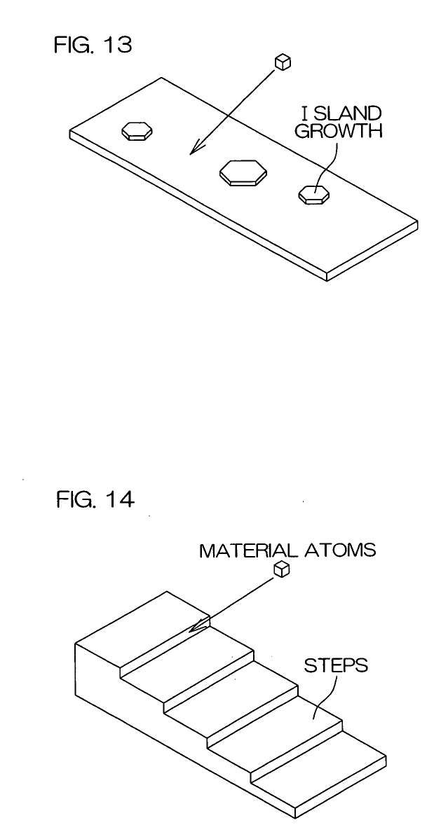

As shown in FIG. 11, the gallium nitride semiconductor light emitting device may be constructed so that the P-type GaN compound semiconductor layer 26 formed on the active layer 25 has a mesa-shaped (truncated) portion and the P-side electrode 31 is provided on a top face of the mesa-shape portion. This arrangement allows for current concentration.

As shown in FIG. 12, the gallium nitride semiconductor light emitting device may be constructed so that the P-type GaN compound semiconductor layer 26 formed on the active layer 25 has a ridge-shaped portion 26A, higher resistance layers 27 for current narrowing are provided on opposite sides of the ridge-shaped portion 26A, and the P-side electrode 31 is connected to a top face of the ridge-shaped portion 26A. The higher resistance layers 27 may be formed of an insulative film such as of SiO_{2.}

The construction shown in FIG. 11 or 12 allows for current concentration, so that electrons and positive holes are efficiently recombined in the active layer 25. This ensures a higher light emitting efficiency.

While preferred embodiments of the present invention have thus been described, the present invention may be embodied in any other ways. In the embodiments described above, the stripes of the stripe pattern formed on the substrate 1 are equidistantly spaced, but are not necessarily required to be equidistantly spaced. For example, some of the stripes maybe spaced a greater distance, whereby a distance between junctions of the striped GaN compound semiconductor layers 72 can be increased. Thus, a lower dislocation density region in which dislocation defects attributable to the junctions are present at a reduced density can be provided. Therefore, the light emitting efficiency can be improved by providing the P-side electrode 31 on the lower dislocation density region.

In the embodiments described above, the GaN compound semiconductor layer 7 is of the N-type by way of example, but may be of the P-type. In this case, the GaN compound semiconductor layer 26 provided on the P-type GaN compound semiconductor layer 7 with the intervention of the active layer 25 is of the N-type.

In the embodiments described above, the sapphire substrate, the silicon carbide substrate or the aluminum nitride substrate is used as the substrate 1 by way of example, but a GaN substrate may be used as the substrate 1. In this case, the need for providing the buffer layer 2 and the underlying GaN film 5 is obviated. After mask layers are formed in a stripe pattern on the surface of the GaN substrate or undulations are formed in a stripe pattern in the surface of the GaN substrate, a GaN compound semiconductor layer is formed by epitaxial growth. However, it is generally difficult to synthesize a GaN crystal in bulk, so that the use of the sapphire substrate, the silicon carbide substrate or the aluminum nitride substrate facilitates the production of the device.

Other examples of the substrate 1 include a LiNbO₃ substrate and a silicon substrate. Where the LiNbO₃ substrate is used, the major surface of the LiNbO₃ substrate is offset from a (100) plane by offset angles of 0.1 degree to 0.5 degrees defined with respect to two crystal axes perpendicular to each other within the (100) plane. Where the silicon substrate is used, the major surface of the silicon substrate is offset from a (111) plane by offset angles of 0.1 degree to 0.5 degrees defined with respect to two crystal axes perpendicular to each other within the (111) plane.

While the present invention has been described in detail by way of the embodiments thereof, it should be understood that the foregoing disclosure is merely illustrative of the technical principles of the present invention but not limitative of the same. The spirit and scope of the present invention are to be limited only by the appended claims.

This application corresponds to Japanese Unexamined Patent Publication No. 2004-302975 filed with the Japanese Patent Office on Oct. 18, 2004, the disclosure of which is incorporated herein by reference.

What is claimed is:

1. A semiconductor device production method comprising the steps of:
forming a linear gallium nitride stripe pattern on a major surface of a substrate, the major surface of the substrate being offset from a predetermined crystal plane by offset angles of 0.1 degree to 0.5 degrees respectively defined with respect to a first crystal axis and a second crystal axis parallel to the predetermined crystal plane, the linear gallium nitride stripe pattern extending along the first crystal axis; and
growing a gallium nitride compound semiconductor crystal along the predetermined crystal plane by selective lateral epitaxial growth to form a gallium nitride compound semiconductor layer on the major surface of the substrate formed with the gallium nitride stripe pattern.

2. A semiconductor device production method as set forth in claim 1, wherein
the first crystal axis and the second crystal axis are perpendicular to each other.

3. A semiconductor device production method as set forth in claim 1, wherein
the substrate is a substrate selected from the group consisting of a sapphire substrate, a silicon carbide substrate, an aluminum nitride substrate and a gallium nitride substrate, and
the predetermined crystal plane is a C-plane.

4. A semiconductor device production method as set forth in claim 1, wherein
the substrate is an LiNbO₃ substrate, and
the predetermined crystal plane is a (100) plane.

5. A semiconductor device production method as set forth in claim 1, wherein
the substrate is a silicon substrate, and
the predetermined crystal plane is a (111) plane.

6. A semiconductor device production method as set forth in claim 1, wherein
the stripe forming step comprises the step of forming a linear stripe mask having linear openings along the first crystal axis for suppressing the growth of the gallium nitride compound semiconductor crystal to define striped linear gallium nitride exposure portions exposed from the openings of the mask.

7. A semiconductor device production method as set forth in claim 1, wherein
the stripe forming step comprises the step of forming undulations in a linear stripe pattern along the first crystal axis in the major surface of the substrate.

8. A semiconductor device production method as set forth in claim 1, further comprising the step of forming a gallium nitride compound semiconductor film as an underlying film on the major surface of the substrate.

9. A semiconductor device production method as set forth in claim 8, wherein
the stripe forming step comprises the step of processing the underlying gallium nitride compound semiconductor film into a linear stripe pattern extending along the first crystal axis.

10. A semiconductor device production method as set forth in claim 1, wherein
the epitaxial growth step for the formation of the gallium nitride compound semiconductor layer comprises the step of introducing an impurity of a first conductivity into the gallium nitride compound semiconductor layer during the epitaxial growth so that the gallium nitride compound semiconductor layer is formed as having the first conductivity,
the method further comprising the steps of:
forming an active layer on the gallium nitride compound semiconductor layer, the active layer being capable of emitting light by recombination of an electron and a positive hole; and
forming a second gallium nitride compound semiconductor layer having a second conductivity different from the first conductivity on the active layer.

11. A substrate comprising a major surface offset from a predetermined crystal plane by offset angles of 0.1 degree to 0.5 degrees respectively defined with respect to a first crystal axis and a second crystal axis parallel to the predetermined crystal plane.

12. A semiconductor device comprising:
a substrate having a major surface offset from a predetermined crystal plane by offset angles of 0.1 degree to 0.5 degrees respectively defined with respect to a first crystal axis and a second crystal axis parallel to the predetermined crystal plane; and
a gallium nitride compound semiconductor layer formed on the major surface of the substrate by epitaxial growth.

13. A semiconductor device as set forth in claim 12, wherein
the gallium nitride compound semiconductor layer is a gallium nitride compound semiconductor layer having a first conductivity,
the semiconductor device further comprising:
an active layer provided on the gallium nitride compound semiconductor layer, the active layer being capable of emitting light by recombination of an electron and a positive hole; and
a gallium nitride compound semiconductor layer provided on the active layer and having a second conductivity different from the first conductivity.
